(19) United States
(12) Patent Application Publication
(10) Pub. No.: US 2025/0176307 A1
(43) Pub. Date: May 29, 2025

(54) OPTICAL SENSOR

(71) Applicant: CANON KABUSHIKI KAISHA, Tokyo (JP)

(72) Inventors: KAZUTAKA YAGUCHI, Shizuoka (JP); TAKUYA MUKAIBARA, Shizuoka (JP)

(21) Appl. No.: 18/950,737

(22) Filed: Nov. 18, 2024

(30) Foreign Application Priority Data
Nov. 27, 2023 (JP) 2023-199630

(51) Int. Cl. H01L 31/0232; H01L 25/16; H01L 31/12

(52) U.S. Cl. CPC H10F 77/413; H01L 25/167; H10F 55/18

(57) ABSTRACT

An optical sensor includes a pattern extending in a first direction substantially parallel to a line connecting two land centers that are connected to the light emitting unit. The pattern in the first direction is formed on at least one of right and left relative to the line connecting the two land centers. The optical sensor also includes a pattern extending in a direction between lands of the light emitting unit. The direction between the lands of the light emitting unit is a second direction substantially perpendicular to the first direction.

### BACKGROUND

### Field of the Disclosure

The present disclosure relates to a stray light reduction method reducing stray light that occurs via a substrate to enhance detection accuracy of an optical sensor.

### Description of the Related Art

Some optical sensors include a light receiving unit that receives light reflected from a portion on which light emitted from a light emitting unit mounted on a substrate is projected. The light received by the light receiving unit includes unintended light (stray light) via the substrate from the light emitting unit. The stray light that enters the light receiving unit can degrade the accuracy of detections by the optical sensor. To prevent stray light entering a light receiving unit, Japanese Patent Application Laid-Open No. 11-354832, Japanese Patent Application Laid-Open No. 2006-267644, and Japanese Patent Application Laid-Open No. 2019-197072 discuss, as a countermeasure, black resist, light-shielding coating solution (silk), and a pattern, respectively, each of which covers the surface of the substrate, to reduce stray light entering the substrate.

The methods discussed in Japanese Patent Application Laid-Open No. 11-354832 and Japanese Patent Application Laid-Open No. 2006-267644 can however be insufficient as a countermeasure against stray light when black resist and light-shielding coating solution (hereinafter, black resist and light-shielding coating solution are collectively referred to as a light-shielding member) cannot be used due to cost or equipment constraints on substrate manufacturing, or they are unevenly formed. Consequently, stray light is an issue if a light-shielding member cannot be used, or it is unevenly formed. In addition, Japanese Patent Application Laid-Open No. 2019-197072 generates a concern of failure in mounting parts due to expansion of mounting lands that tends to dissipate heat in mounting parts.

### SUMMARY

Some embodiments of the present disclosure are directed to provision of an optical sensor that reduces stray light while parts are reliably mountable on a substrate regardless of whether a light-shielding member is included or unevenly formed or not.

According to an aspect of the present disclosure, an optical sensor includes a light emitting unit configured to emit light toward an irradiation body, at least one light receiving unit configured to receive light that is reflection of the light emitted from the light emitting unit by the irradiation body, a substrate on which the light emitting unit and the light receiving unit are mounted, and a land pattern formed on the substrate and configured to connect the light emitting unit and the light receiving unit to the substrate. The optical sensor includes at least one pattern extending in a first direction substantially parallel to a line connecting two land centers that are connected to the light emitting unit, the at least one pattern being formed on at least one of right and left relative to the line connecting the two land centers, and a pattern extending in a direction between the lands of the light emitting unit, the direction between the lands of the light emitting unit being a second direction substantially perpendicular to the first direction.

Further features of various embodiments will become apparent from the following description of exemplary embodiments with reference to the attached drawings.

### BRIEF DESCRIPTION OF THE DRAWINGS

FIG. 1 schematically illustrates an optical sensor according to a first exemplary embodiment.

FIGS. 2A through 2D illustrate a countermeasure against stray light in the optical sensor according to the first exemplary embodiment.

FIG. 3 illustrates stray light areas of light emitted from a light emitting diode (LED) to a surface of a substrate.

FIG. 4 illustrates another stray light area of the light emitted from the LED to the substrate surface.

FIGS. 5A through 5D illustrate a countermeasure against stray light with a LED mounting position displaced (rightward) in the optical sensor according to the first exemplary embodiment.

FIGS. 6A and 6B illustrate modifications of the countermeasure against stray light in the optical sensor according to the first exemplary embodiment.

FIGS. 7A to 7D illustrate a countermeasure against stray light in an optical sensor according to a second exemplary embodiment.

FIGS. 8A through 8D illustrate the countermeasure against stray light with a LED mounting position displaced (upward) in the optical sensor according to the second exemplary embodiment.

FIG. 9 illustrates a modification of the countermeasure against stray light in the optical sensor according to the second exemplary embodiment.

### DESCRIPTION OF THE EMBODIMENTS

Hereinafter, exemplary embodiments will be described with reference to the drawings.

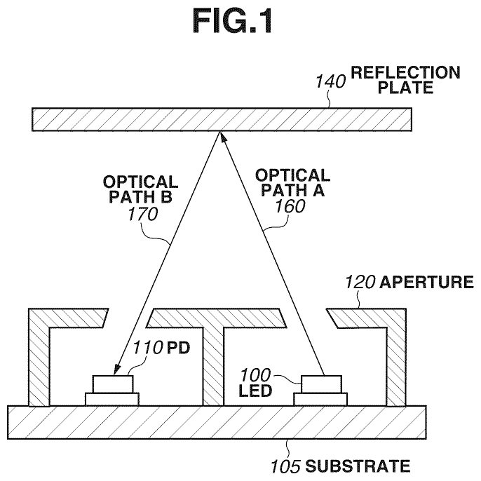

FIG. 1 is a schematic diagram illustrating an optical sensor according to a first exemplary embodiment. The optical sensor includes a light emitting diode (LED) 100 as a light emitting unit (a light emitting element), a photo diode (PD) 110 as a light receiving unit (a light receiving element) that receives light, a substrate 105 on which the LED 100 and the PD 110 are mounted, an aperture 120 that narrows light emitted from the LED 100 and light to be received by the PD 110, and a reflection plate (an irradiation body) 140 that reflects the light from the LED 100. The light emitted by the LED 100 is narrowed by the aperture 120, forming an optical path A 160. The light in the optical path A 160 is reflected by the reflection plate 140. Out of the reflected light, light narrowed by the aperture 120 in an optical path B 170 is received by the PD 110. The reflection plate 140 in the present exemplary embodiment is not limited to such a configuration, and can be made of a substance that reflects light. An example of the reflection plate 140 can be a belt to be used in an image forming apparatus.

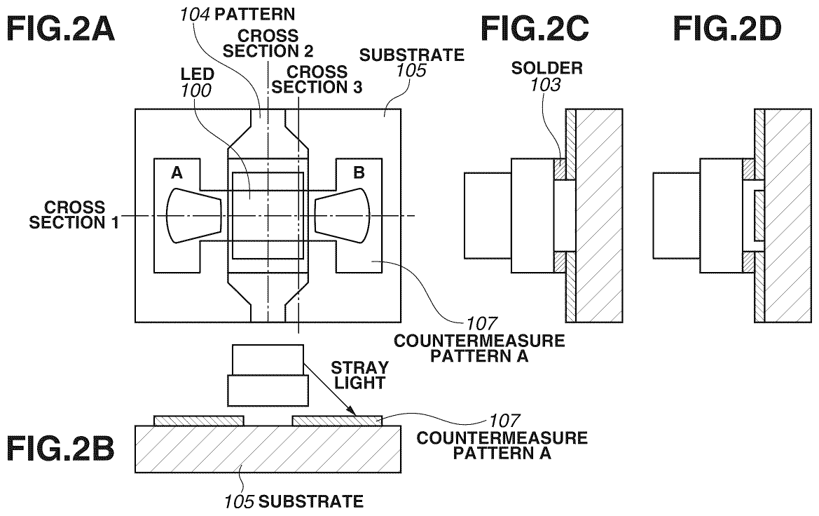

FIGS. 2A through 2D are sectional views each illustrating the substrate 105. FIG. 2A is an enlarged view of an area near the LED 100 above the upper surface of the substrate 105. FIGS. 2B and 2C are sectional views along the dotted lines representing cross sections 1 and 2 illustrated in FIG. 2A. FIG. 2D is a sectional view along the dotted line representing a cross section 3 illustrated in FIG. 2A. A copper foil pattern 104 (hereinafter referred to as a pattern) having a thickness of 35 μm is formed on the surface of the substrate 105, and a solder 103 connects a land of the LED 100 to the pattern (land pattern) 104. A countermeasure pattern A 107 is formed as a stray-light countermeasure of the present exemplary embodiment. The aforementioned pattern thickness is an example of size in manufacture of substrates, and is not limited thereto since manufacturing conditions can be changed.

The light emitted from the LED 100 to the substrate surface forms a radial line from a light emitting element 108 inside the LED 100. In FIG. 2A, light in each of areas A and B enclosed by solid lines is predominantly influenced by stray light. The countermeasure pattern A 107 prevents the light emitted by the LED 100 from entering (straying into) the PD 110 via the substrate 105. The countermeasure pattern A 107 has two features. The first feature is a pattern (hereinafter referred to as a countermeasure pattern 1) that extends in a first direction substantially parallel to a line connecting two land centers and is formed on at least one of the right and the left relative to the line connecting the two land centers. The second feature is a pattern (also referred to as a countermeasure pattern 2) extending in a second direction substantially perpendicular to the first direction. The second direction is a direction between lands of the LED 100. In the present exemplary embodiment, one countermeasure pattern 1 is formed on each of the right and the left.

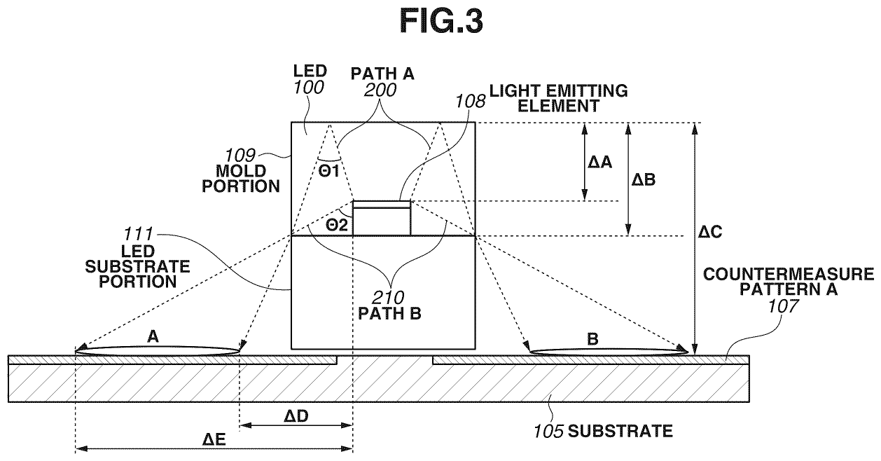

FIG. 3 illustrates a path of light emitted to the substrate surface from the LED 100 illustrated in FIG. 2B. On a path A 200 illustrated in FIG. 3, the light from the light emitting element 108 inside the LED 100 is reflected by a mold portion 109 and then emitted to the substrate surface. Mirror reflection is assumed as an example. On a path B 210, the light from the light emitting element 108 passes through the mold portion 109, and then strikes the surface of substrate. These two paths mainly account for stray light via the substrate, and subject to reduction of stray light in the present exemplary embodiment (shielded by the countermeasure pattern A 107). In the present exemplary embodiment, an LED substrate portion 111 is assumed not to transmit light. For example, the top surface and/or the bottom surface of the LED substrate portion 111 and/is covered as large area as possible with a substrate pattern, a black resist material or a silk material, or a combination of these, shielding the LED substrate portion 111 more effectively from the light. That is, the light emitted to the surface of the substrate on the path A 200 is confined to the range (θ1 or more in FIG. 3) in which the light is not shielded by the LED substrate portion 111. Similarly, the light emitted to the substrate surface on the path B 210 is confined to the range (θ2 or more in FIG. 3) in which the light is not shielded by the LED substrate portion 111.

One example of a method of calculating an area A dominantly subjected to influence of stray light will be described. In the example, ΔA=0.4 mm, ΔB=0.5 mm, and ΔC=1.1 mm, where ΔA is the distance from the light emitting element 108 of the LED 100 to the top surface of the mold portion 109, ΔB is the distance from the upper portion of the LED substrate portion 111 to the top surface of the mold portion 109, and ΔC is the height of the LED 100 as a component (the thickness of the solder 103 is sufficiently negligible). In the example, moreover, 01=35°, where θ1 is the angle between the incident angle to the mold portion 109 on the path A 200 and the reflection angle. In such a case, ΔD=ΔC×tan (θ½)+ΔA×tan (θ½)≈0.473 mm, where ΔD is the distance from the left end of the light emitting element 108 to the right end of the area A. If θ2=60°, ΔE=(ΔC−ΔA)× tan (θ2)≈1.212 mm, where θ2 is the angle between the direction perpendicular to the substrate along the left end portion of the light emitting element 108 and the light emitted from the left end portion of the light emitting element 108, and ΔE is the distance from the left end of the light emitting element 108 to the left end of the area A. As the angle θ2 to 90° is closer, the distance ΔE is longer. As the optical path however is longer, the light intensity is lower. Thus, as the point is farther away from the LED 100, the influence of stray light on the point decreases. In view of the influence of stray light described, the current optical path (=(√((ΔC−ΔA)\hat{ }2+(1.212)\hat{ }2)≈1.399 mm when θ2=60°) is up to its double-length (˜ 2.798 mm), and the distance ΔE can be (√((ΔC−ΔA)\hat{ }2+(2.798)\hat{ }2)≈2.884 mm. The above numeric values depend on the configuration and the optical characteristics of the LED 100 used, and are not limited thereto.

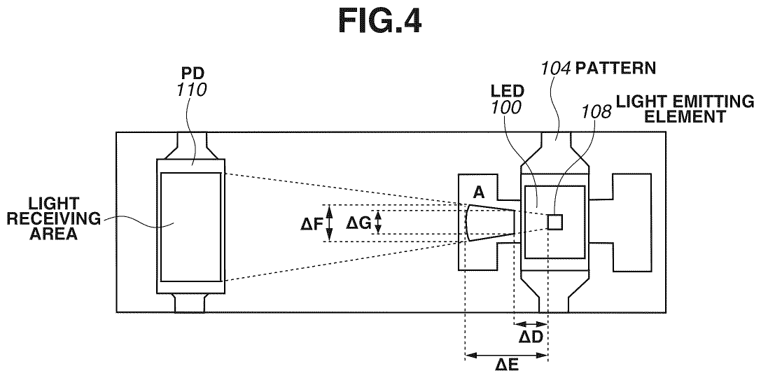

FIG. 4 illustrates one example of the range of the area A, which is predominantly influenced by stray light, illustrated in FIG. 2A.

The light emitted to the surface of the substrate from the light emitting element 108 travels in the substrate, and then enters the light receiving area of the PD 110, which is stray light. Thus, as illustrated in FIG. 4, the area A is a region enclosed by dotted lines connecting the outline of the light emitting element 108 and the light receiving area of the PD 110 and dotted lines representing the range between ΔD or longer and ΔE or shorter from the left end portion of the light emitting element 108. In one example, the light emitting element 108 has a size of 0.1 mm×0.1 mm, the light receiving area of the PD 110 has a longitudinal length of 0.7 mm, and the distance from the left end portion of the light emitting element 108 to the right end portion of the light receiving area is 5 mm. When the center of the light receiving area and the center of the light emitting element 108 are linearly arranged and ΔD=0.473 mm and ΔE=1.212 mm, ΔF and ΔG illustrated in FIG. 4 are respectively determined to be ΔF≈0.245 mm and ΔG≈0.157 mm.

When a PD (not illustrated) that differs from the PD 110 is disposed opposite to the PD 110 across the LED 100, the area B can be determined by a method similar to that used in the example of the area A. On the other hand, even with a different PD absent, the light emitted to the area B is diffusely reflected in the substrate 105 and then enters the PD 110, which is stray light that however has lower influence than that in the area A. As a result, the stray light in the area B also is subject to reduction with the countermeasure pattern A 107. ΔD and ΔE in the area B are determined by methods similar to those in the area A, the descriptions thereof are omitted. In addition, ΔF and ΔG in the area B can be the same as those in the area A, or can be determined under another optical condition. As described above, the longer the optical path, the lower the light intensity. Thus, for example, ΔF and ΔG in the area B can be determined based on a range in which light intensity is sufficiently reduced or a range in which light is shielded by the LED substrate portion 111.

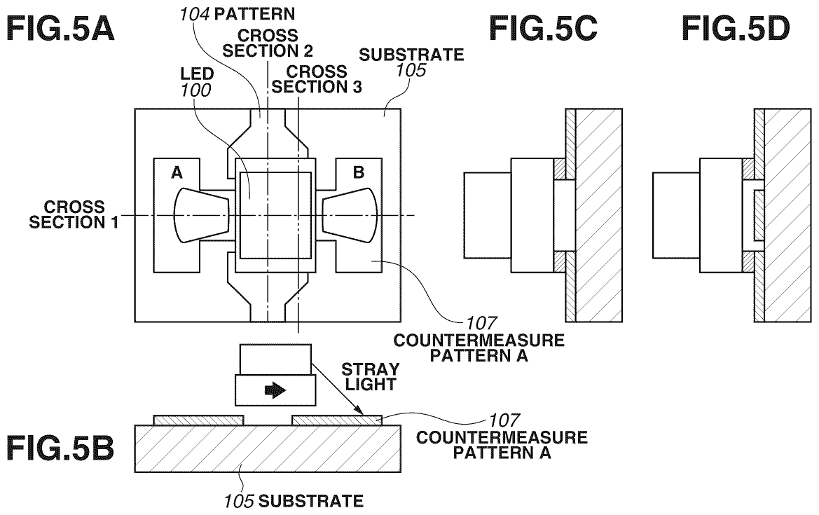

To reduce the stray light which occurs in the areas A and B in consideration of the above details, the countermeasure pattern A 107 includes the countermeasure patterns 1 and 2. In the countermeasure pattern 1, the distance to a land can be determined based on constraints on substrate manufacturing (e.g., the interval between patterns is 0.2 mm or more). As for the distance to the countermeasure pattern 1, positions of the areas A and B are changed depending on the position of the light emitting element 108 inside the LED 100. Thus, the distances to the countermeasure pattern 1 can be unequal. It is sufficient that the countermeasure pattern 1 has a width and a length in a form that covers at least the above-described areas A and B. The countermeasure pattern A 107 includes the countermeasure pattern 2 in a direction perpendicular to the countermeasure pattern 1 and extending in a direction between lands of the LED 100. Such an arrangement reduces stray light even if the position of mounting the LED 100 is displaced in a right-left direction in FIG. 5B. FIGS. 5A through 5D illustrate an example case in which the position of the component is displaced in a right direction. The width and the length of the countermeasure pattern 2 can be determined in consideration of covering the above-described areas A and B and a variation in the position of mounting the component. For example, when the variation in the mounting position is ±0.2 mm, a pattern larger than each of the areas A and B by at least 0.2 mm can be formed. Further, a pattern extending from one direction of a land of the LED 100 and a pattern extending from another direction can be joined below the LED 100.

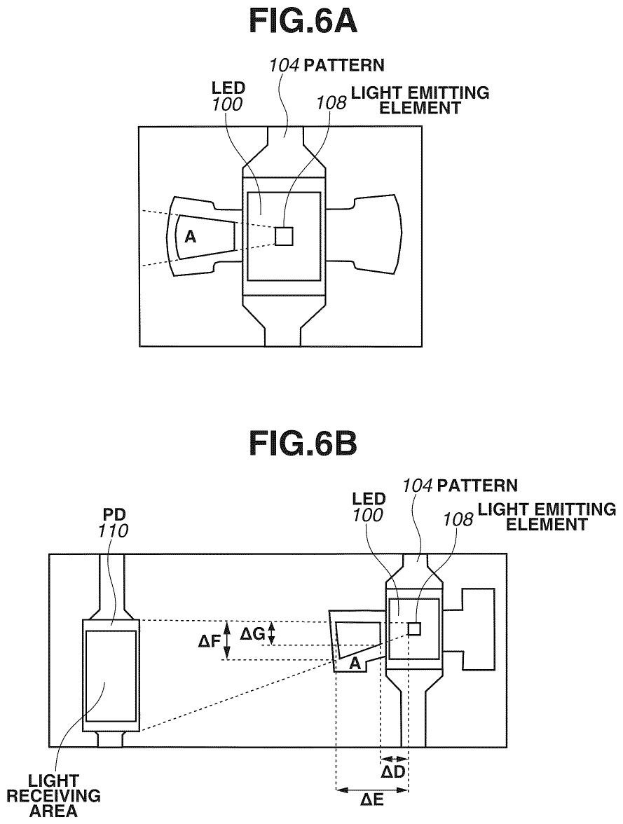

In the drawings of the present exemplary embodiment, the portion of joining the countermeasure pattern 1 with the countermeasure pattern 2 forms a right angle. However, the countermeasure patterns 1 and 2 can be joined at a gentle angle. As long as stray light in the areas A and B can be reduced, the countermeasure pattern A 107 can have a shape that has exactly parallel and perpendicular lines or have a different shape that is slightly inclined or has a curved line as illustrated in FIG. 6A. Since the area to be shielded from light is changed depending on the arrangement of the light receiving element, the shape of the countermeasure pattern A 107 can be slightly modified as illustrated in FIG. 6B. Consequently, the countermeasure pattern A 107 formed on the substrate can reduce the stray light that occurs via the substrate near the LED 100 while satisfying component mountability.

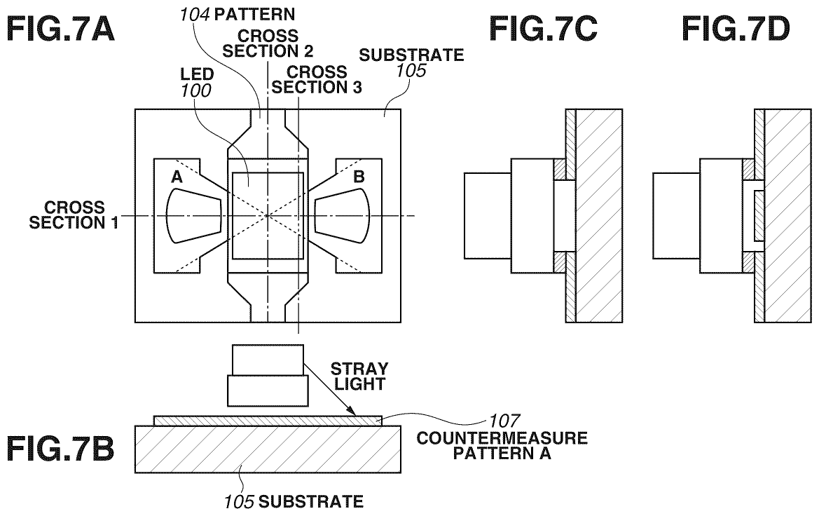

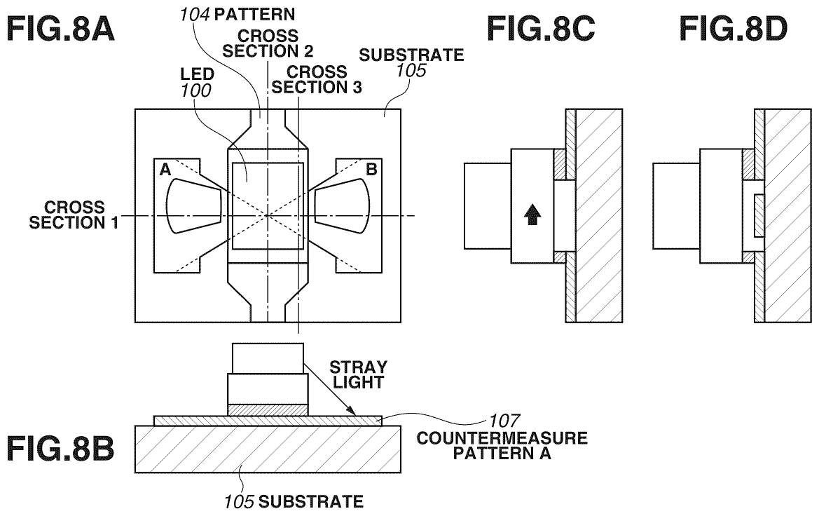

A second exemplary embodiment will be described. The configuration according to a second exemplary embodiment is similar to that according to the first exemplary embodiment. As illustrated in FIGS. 7A through 7D, a countermeasure pattern 2 has a radial shape from the center of an LED 100 (dotted lines passing the center of the LED 100), which allows stray light to be reduced even with the mounting position displaced in a vertical direction. In addition, FIG. 7B is a sectional view along a dotted line indicated by a cross section 1 illustrated in FIG. 7A, and FIG. 7C is a sectional view along a dotted line indicated by a cross section 2 illustrated in FIG. 7A. FIG. 7D is a sectional view along a dotted line indicated by a cross section 3 illustrated in FIG. 7A. Like numbers refer to like components similar to those of the first exemplary embodiment, and the descriptions thereof are omitted. FIGS. 8A through 8D are diagrams illustrating when the position of mounting the LED 100 in FIGS. 7A through 7D is displaced upward. With the position of mounting the LED 100 displaced, the areas subjected to the predominant influence of stray light are shifted as illustrated with areas A and B enclosed by solid lines in FIG. 8A. In the present exemplary embodiment, the countermeasure pattern 2 has a radial shape from the center of the LED 100 (the dotted lines passing the center of the LED 100), allowing stray light to be reduced even with areas subjected to the dominant influence of stray light shifted due to the displacement of the mounting position in a vertical direction. In FIG. 2A, the width of the countermeasure pattern 2 is not increased in consideration of interference with a land of the LED 100. In FIG. 7A, the radial lines passing the center of the LED 100 can be determined based on the variation in mounting of the LED 100 in a vertical direction. For example, when the variation in mounting is ±0.2 mm, the angles of the radial lines can be determined in consideration of ±0.2 mm that corresponds to a shift of the areas subjected to the predominant influence of stray light as indicated by a dotted line illustrated in FIG. 7A. In the present exemplary embodiment, a light emitting element 108 inside the LED 100 is in the center of the LED 100. However, with the light emitting element 108 disposed out of the center of the LED 100, in determining the shape of the countermeasure pattern 2, radial lines can be from the center of the light emitting element 108. In the second exemplary embodiment, parallel and vertical lines include exactly parallel and perpendicular lines and a slightly inclined or curved line. Moreover, the area to be shielded from light is changed depending on the arrangement of the light receiving element, so that the countermeasure pattern A 107 desirably has a slightly deformed shape. Thus, the countermeasure pattern 2 according to the present exemplary embodiment can be formed in a manner that the center of the LED 100 and the light receiving element are connected to each other.

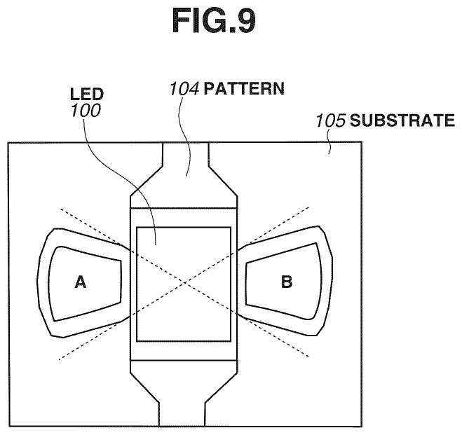

If the stray light can be prevented from entering in the areas A and B with the countermeasure pattern 2 having the shape according to the present exemplary embodiment, no countermeasure pattern 1 can be arranged. Similarly, as long as the stray light in the areas A and B can be reduced, the countermeasure pattern 2 can have a different shape as illustrated in FIG. 9. Thus, the countermeasure pattern 2 has a radial shape from the center of the LED 100 (a dotted line passing the center of the LED 100), reducing the stray light even with the mounting position displaced in a vertical direction.

### [Supplementary Note]

The above-described exemplary embodiments disclose at least an optical sensor as follows.

### (Item 1)

An optical sensor comprising:
a light emitting unit configured to emit light toward an irradiation body;
at least one light receiving unit configured to receive light that is reflection of the light emitted from the light emitting unit by the irradiation body;
a substrate on which the light emitting unit and the light receiving unit are mounted; and
a land pattern formed on the substrate and configured to connect the light emitting unit and the light receiving unit to the substrate,
wherein the optical sensor includes:
   at least one pattern extending in a first direction substantially parallel to a line connecting two land centers that are connected to the light emitting unit, the at least one pattern being formed on at least one of right and left relative to the line connecting the two land centers; and
   a pattern extending in a direction between the lands of the light emitting unit, the direction between the lands of the light emitting unit being a second direction substantially perpendicular to the first direction.

### (Item 2)

The optical sensor according to Item 1, wherein the first direction substantially parallel to the line is a direction parallel to the line, and the second direction substantially perpendicular to the first direction is a direction perpendicular to the first direction.

### (Item 3)

The optical sensor according to Items 1 to 2, wherein the at least one pattern extending in the first direction and formed on the at least one of right and left relative to the line connecting the two land centers includes one pattern on the right relative to the line and another pattern on the left relative to the line, the lands of the light emitting unit being between the one pattern and the other pattern.

### (Item 4)

The optical sensor according to Items 1 to 3, wherein the pattern extending in the direction between the lands of the light emitting unit as the second direction is radially formed from a center of the light emitting unit.

### (Item 5)

The optical sensor according to Items 1 to 4, wherein the at least one pattern extending in the first direction and formed on at least one of right and left relative to the line connecting the two land centers has a length in the first direction, the length being a range or longer, the range formed by connecting an outline of the light emitting unit and an outline of the light receiving unit.

### (Item 6)

The optical sensor according to Items 1 to 5, wherein the pattern extending in the direction between the lands of the light emitting unit as the second direction is a pattern in which a pattern extending from one direction of a land of the light emitting unit and a pattern extending from other direction is joined below the light emitting unit.

### (Item 7)

An optical sensor comprising:
a light emitting unit configured to emit light toward an irradiation body;
at least one light receiving unit configured to receive light that is reflection of the light emitted from the light emitting unit by the irradiation body;
a substrate on which the light emitting unit and the light receiving unit are mounted; and
a land pattern formed on the substrate and configured to connect the light emitting unit and the light receiving unit to the substrate,
wherein the optical sensor includes a pattern extending in a direction between lands of the light emitting unit, the direction between the lands of the light emitting unit being a second direction substantially perpendicular to a line connecting two land centers that are connected to the light emitting unit, and
wherein the pattern extending in the direction between the lands of the light emitting unit as the second direction is radially formed from a center of the light emitting unit.

### (Item 8)

The optical sensor according to Items 1 to 7, wherein the at least one light receiving unit comprises two light receiving units, and the two light receiving units are each arranged at a corresponding position of positions between which the light emitting unit is arranged.

### (Item 9)

The optical sensor according to Items 1 to 8, wherein the pattern extending in the direction between the lands of the light emitting unit as the second direction is radially formed with a line connecting a center of the light emitting unit and the light receiving unit.

### (Item 10)

The optical sensor according to Items 7 to 9, wherein the second direction substantially perpendicular to the line includes a direction perpendicular to the line.

According to the present disclosure as described above, an optical sensor is provided that reduces stray light while parts are reliably mountable on a substrate regardless of whether a light-shielding member is included or uneven formed or not.

While the present disclosure has described exemplary embodiments, it is to be understood that some embodiments are not limited to the disclosed exemplary embodiments. The scope of the following claims is to be accorded the broadest interpretation so as to encompass all such modifications and equivalent structures and functions.

This application claims priority to Japanese Patent Application No. 2023-199630, which was filed on Nov. 27, 2023 and which is hereby incorporated by reference herein in its entirety.

What is claimed is:

1. An optical sensor comprising:
a light emitting unit configured to emit light toward an irradiation body;
at least one light receiving unit configured to receive light that is reflection of the light emitted from the light emitting unit by the irradiation body;
a substrate on which the light emitting unit and the light receiving unit are mounted; and
a land pattern formed on the substrate and configured to connect the light emitting unit and the light receiving unit to the substrate,
wherein the optical sensor includes:
at least one pattern extending in a first direction substantially parallel to a line connecting two land centers that are connected to the light emitting unit, the at least one pattern being formed on at least one of right and left relative to the line connecting the two land centers; and
a pattern extending in a direction between the lands of the light emitting unit, the direction between the lands of the light emitting unit being a second direction substantially perpendicular to the first direction.

2. The optical sensor according to claim 1, wherein the first direction substantially parallel to the line is a direction parallel to the line, and the second direction substantially perpendicular to the first direction is a direction perpendicular to the first direction.

3. The optical sensor according to claim 1, wherein the at least one pattern extending in the first direction and formed on the at least one of right and left relative to the line connecting the two land centers includes one pattern on the right relative to the line and another pattern on the left relative to the line, the lands of the light emitting unit being between the one pattern and the other pattern.

4. The optical sensor according to claim 1, wherein the pattern extending in the direction between the lands of the light emitting unit as the second direction is radially formed from a center of the light emitting unit.

5. The optical sensor according to claim 1, wherein the at least one pattern extending in the first direction and formed on at least one of right and left relative to the line connecting the two land centers has a length in the first direction, the length being a range or longer, the range formed by connecting an outline of the light emitting unit and an outline of the light receiving unit.

6. The optical sensor according to claim 1, wherein the pattern extending in the direction between the lands of the light emitting unit as the second direction is a pattern in which a pattern extending from one direction of a land of the light emitting unit and a pattern extending from other direction is joined below the light emitting unit.

7. An optical sensor comprising:
a light emitting unit configured to emit light toward an irradiation body;
at least one light receiving unit configured to receive light that is reflection of the light emitted from the light emitting unit by the irradiation body;
a substrate on which the light emitting unit and the light receiving unit are mounted; and
a land pattern formed on the substrate and configured to connect the light emitting unit and the light receiving unit to the substrate,
wherein the optical sensor includes a pattern extending in a direction between lands of the light emitting unit, the direction between the lands of the light emitting unit being a second direction substantially perpendicular to a line connecting two land centers that are connected to the light emitting unit, and
wherein the pattern extending in the direction between the lands of the light emitting unit as the second direction is radially formed from a center of the light emitting unit.

8. The optical sensor according to claim 1, wherein the at least one light receiving unit comprises two light receiving units, and the two light receiving units are each arranged at a corresponding position of positions between which the light emitting unit is arranged.

9. The optical sensor according to claim 1, wherein the pattern extending in the direction between the lands of the light emitting unit as the second direction is radially formed with a line connecting a center of the light emitting unit and the light receiving unit.

10. The optical sensor according to claim 7, wherein the second direction substantially perpendicular to the line includes a direction perpendicular to the line.
